(19) United States
(12) Patent Application Publication
(10) Pub. No.: US 2013/0313666 A1
(43) Pub. Date: Nov. 28, 2013

(54) RADIATION IMAGE CAPTURING DEVICE

(71) Applicant: Konica Minolta, Inc., Tokyo (JP)

(72) Inventors: Tetsuo NISHI, Tokyo (JP); Kenji OKAJIMA, Kusatsu-shi (JP)

(73) Assignee: Konica Minolta, Inc., Tokyo (JP)

(21) Appl. No.: 13/900,122

(22) Filed: May 22, 2013

(30) Foreign Application Priority Data
May 23, 2012 (JP) 2012-117063

(51) Int. Cl. H01L 27/146

(52) U.S. Cl. CPC H01L 27/14603
USPC 257/428

(57) ABSTRACT

A radiation image capturing device includes scan lines, signal lines, radiation detection elements and switch elements. With respect to each of the radiation detection elements, a first distance between an edge of the radiation detection element and an edge of a scan line and/or a second distance between an edge of the radiation detection element and an edge of a signal line is set within a range acceptable as a manufacturing error. The center of the range is a value which maximizes a ratio obtained by dividing the area of the radiation detection element by a first parasitic capacitance between the radiation detection element and the scan line and/or a second parasitic capacitance between the radiation detection element and the signal line.

### BACKGROUND OF THE INVENTION

1. Field of the Invention

The present invention relates to a radiation image capturing device and in particular, relates to a radiation image capturing device including radiation detection elements which are two-dimensionally arranged.

2. Description of Related Art

A variety of so-called direct-type radiation image capturing devices and indirect-type radiation image capturing devices have been developed. The direct-type radiation image capturing device generates electric charge with detection elements in accordance with the dose of irradiated radiation such as X-rays, and converts the generated charge into electric signals. The indirect-type radiation image capturing device converts irradiated radiation with a scintillator or the like into a light having a different wavelength from the radiation such as visible light, generates electric charge with photoelectric conversion elements such as photodiodes in accordance with the energy of the converted light thereafter, and converts the generated charge into electric signals (i.e., image data). In the present invention, the detection elements in the direct-type radiation image capturing device and the photoelectric conversion elements in the indirect-type radiation image capturing device are referred to as radiation detection elements.

Each of these types of radiation image capturing devices is known as an FPD (Flat Panel Detector), and is conventionally configured as a so-called special-purpose device (or fixed device) which is united with a supporting stand (see Japanese Patent Application Laid-Open Publication No. 9-73144). However, in recent years, a portable radiation image capturing device which includes radiation detection elements housed in a housing has been developed and in practical use (see Japanese Patent Application Laid-Open Publication Nos. 2006-058124, and 6-342099, for example).

In such a radiation image capturing device, a plurality of scan lines 5 and a plurality of signal lines 6 are typically arranged in such a way as to intersect each other to form small regions r as shown in FIG. 3 and FIG. 4 (described later), and a plurality of radiation detection elements 7 are two-dimensionally arranged in matrix form in the respective small regions r. Each of the radiation detection elements 7 is connected to a switch element 8 which is constituted of a thin film transistor (hereinafter referred to as TFT) or the like.

In general, radiation is sent from the radiation source of a radiation generator to a radiation image capturing device through a subject for radiation image capturing. After the image capturing, ON-state voltage is applied from a gate driver 15b consecutively to the lines L1 to Lx among the scan lines 5 to put the TFTs 8 into ON-state consecutively. The electric charge which is generated in the radiation detection elements 7 and accumulated by irradiation is discharged consecutively to the signal lines 6. Then, the electric charge is read as image data D at each of the reading circuits 17.

By the way, radiation images obtained with a radiation image capturing device may be used for diagnosis in the medical field. For example, the radiation image capturing device may be used for radiographing the body of a patient, i.e., a subject, to obtain a radiation image of a lesion area. Since the smallest interval which can be recognized by the human eye is considered to be about 100 μm, the interval L2 (or pixel pitch L2, shown in FIG. 8, described later) between the scan lines 5 and between the signal lines 6 is also set to about 100 μm. In the small regions formed by the scan lines 5 and the signal lines 6, the radiation detection elements 7 are provided, respectively.

In each of the small regions formed by the scan lines 5 and the signal lines 6 formed at a given pixel pitch L2, the aperture ratio (or the area) of the radiation detection element 7 has conventionally been made as large as possible in order to increase the signal value (or image data D) detected at the radiation detection element 7, which is formed minutely as described above, as much as possible.

As the aperture ratio of the radiation detection element 7 gets larger for the given pixel pitch L2, however, the distance between an edge of the radiation detection element 7 and a corresponding scan line 5 and between an edge of the radiation detection element 7 and a corresponding signal line 6 gets shorter, which causes an increase in the parasitic capacitance C formed between the radiation detection element 7 and the scan line 5, and the parasitic capacitance C formed between the radiation detection element 7 and the signal line 6. Further, when the parasitic capacitance C gets larger, a signal line capacitance increases. As a result, a noise in each of the reading circuits 17 gets larger in proportion to the signal line capacitance.

As described above, with an increase in the aperture ratio of the radiation detection element 7, the distance between the radiation detection element 7 and the scan line 5, and between the radiation detection element 7 and the signal line 6 gets shorter, which results in an increase in the signal line capacitance. As a result, there is a deterioration in the signal-to-noise ratio (hereinafter referred to as S/N) of image data D to be read from the radiation detection element 7 because of an increase in “N” (noise) superimposed on image data D, although “S” (signal) or the value of image data D to be read increases.

In view of the above, designers have conventionally designed based on experience such that the aperture ratio of the radiation detection element 7 is as large as possible while the distance between the radiation detection element 7 and the scan line 5, and between the radiation detection element 7 and the signal line 6 is not too short.

In view of such circumstances, the inventors have spent a lot of time on conducting studies to find the best distance between the radiation detection element 7 and the scan line 5, and the best distance between the radiation detection element 7 and the signal line 6 (i.e., so-called best position). As a result, the inventors have found that the S/N varies depending on the distance between the radiation detection element 7 and the scan line 5, and the distance between the radiation detection element 7 and the signal line 6, and that a distance which produces the best S/N exists. Further, the inventors have found that the distance which produces the best S/N varies depending on a pixel pitch (i.e., the interval between adjacent scan lines 5, and between adjacent signal lines 6).

The inventors have found that image data D can be read from the radiation detection elements 7 with a high S/N by setting the distance between the radiation detection element 7 and the scan line 5, and the distance between the radiation detection element 7 and the signal line 6 to the value which produces the best S/N, instead of merely making the distance smaller or larger.

### SUMMARY OF THE INVENTION

The present invention, which has been made in view of the above-mentioned circumstances, provides a radiation image capturing device which can read image data from the radiation detection elements with a high S/N, and can form images of high quality.

According to an aspect of a preferred embodiment of the present invention, there is provided a radiation image capturing device including: a plurality of scan lines; a plurality of signal lines arranged to intersect the scan lines; a plurality of radiation detection elements respectively disposed in regions formed by the scan lines and the signal lines; a plurality of switch elements which are connected to the scan lines, and discharge electric charge accumulated in the radiation detection elements to the signal lines when an ON-state voltage is applied to the scan lines, wherein, with respect to each of the radiation detection elements, a first distance between an edge of the radiation detection element and an edge of a scan line of the scan lines and/or a second distance between an edge of the radiation detection element and an edge of a signal line of the signal lines is set within a range acceptable as a manufacturing error; and wherein the center of the range is a value which maximizes a ratio obtained by dividing the area of the radiation detection element by a first parasitic capacitance between the radiation detection element and the scan line and/or a second parasitic capacitance between the radiation detection element and the signal line.

### BRIEF DESCRIPTION OF THE DRAWINGS

The above and other objects, advantages and features of the present invention will become more fully understood from the detailed description given hereinbelow and the appended drawings which are given byway of illustration only, and thus are not intended as a definition of the limits of the present invention, and wherein:

FIG. 1 is a perspective view showing the appearance of a radiation image capturing device in accordance with the present embodiment;

FIG. 2 is a cross-sectional view taken along the line X-X of FIG. 1;

FIG. 3 is a plan view showing the configuration of a substrate of the radiation image capturing device;

FIG. 4 is an enlarged view showing the configuration of a radiation detection element and a TFT formed in each small region on the substrate shown in FIG. 3;

FIG. 5 is a cross-sectional view taken along the line Y-Y of FIG. 4 for explaining the configurations of the radiation detection element and the TFT;

FIG. 6 is a lateral view for explaining the substrate provided with a flexible circuit substrate, a PCB substrate, and the like.

FIG. 7 is a block diagram showing an equivalent circuit of the radiation image capturing device;

FIG. 8 is a view of scan lines, signal lines and a radiation detection element related to only one pixel of a sensor panel of the radiation image capturing device in accordance with the present embodiment;

FIG. 9A is a graph representing the relation of the area of the radiation detection element to the distance between the radiation detection element and the scan/signal line when the pixel pitch is set to 175 μm;

FIG. 9B is a graph representing the relation of the parasitic capacitance formed between the radiation detection element and the scan/signal line to the distance between the radiation detection element and the scan/signal line when the pixel pitch is set to 175 μm;

FIG. 10 is a graph representing the relation of the S/N to the distance between the radiation detection element and the scan/signal line in the case shown in FIGS. 9A and 9B;

FIG. 11A is a graph representing the relation of the area of the radiation detection element to the distance between the radiation detection element and the scan/signal line when the pixel pitch is set to 100 μm;

FIG. 11B is a graph representing the relation of the parasitic capacitance formed between the radiation detection element and the scan/signal line to the distance between the radiation detection element and the scan/signal line when the pixel pitch is set to 100 μm;

FIG. 12 is a graph representing the relation of the S/N to the distance between the radiation detection element and the scan/signal line in the case shown in FIGS. 11A and 11B;

FIG. 13 is a graph showing curves representing the relation of the S/N to the distance between the radiation detection element and the scan/signal line for each pixel pitch;

FIG. 14 is a graph where the distance L1max which maximizes the S/N is plotted for each pixel pitch;

FIG. 15 is a graph showing that the area enclosed by the chain line around the straight line shown in FIG. 14 is to be set as the distance between the radiation detection element and the scan/signal line;

FIG. 16 is a cross-sectional view showing a part of a conventional radiation detection element;

FIG. 17 a cross-sectional view showing a part of a radiation detection element in the case where an inorganic protective layer is not provided over the second electrode of the radiation detection element; and

FIG. 18 is overhead view of the part shown in FIG. 17.

### DESCRIPTION OF THE PREFERRED EMBODIMENTS

In the following, a radiation image capturing device in accordance with embodiments of the present invention is described with reference to the drawings.

The radiation image capturing device described below is a so-called indirect-type radiation image capturing device which includes a scintillator and converts irradiated radiation into a light having a different wavelength from the radiation, such as visible light, to obtain electrical signals. The present invention, however, may be applied to a so-called direct-type radiation image capturing device which detects radiation directly with radiation detection elements without a scintillator.

The radiation image capturing device described below is a so-called portable device. The present invention, however, may be applied to a special-purpose radiation image capturing device which is united with a supporting stand.

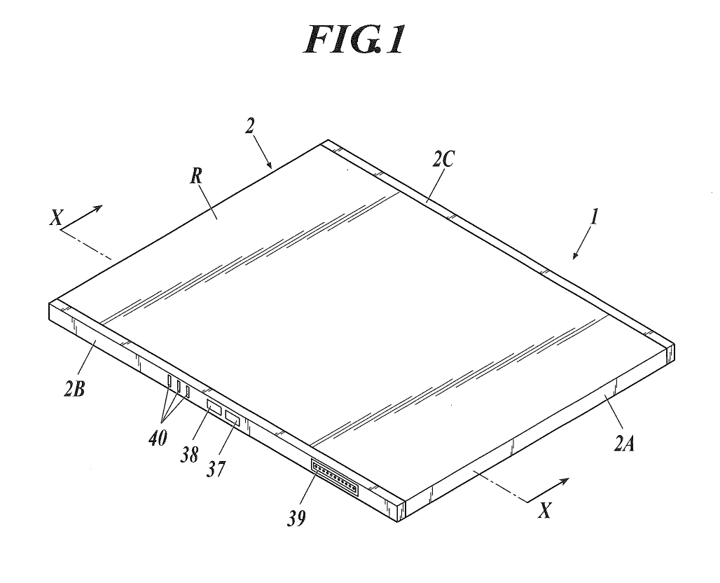

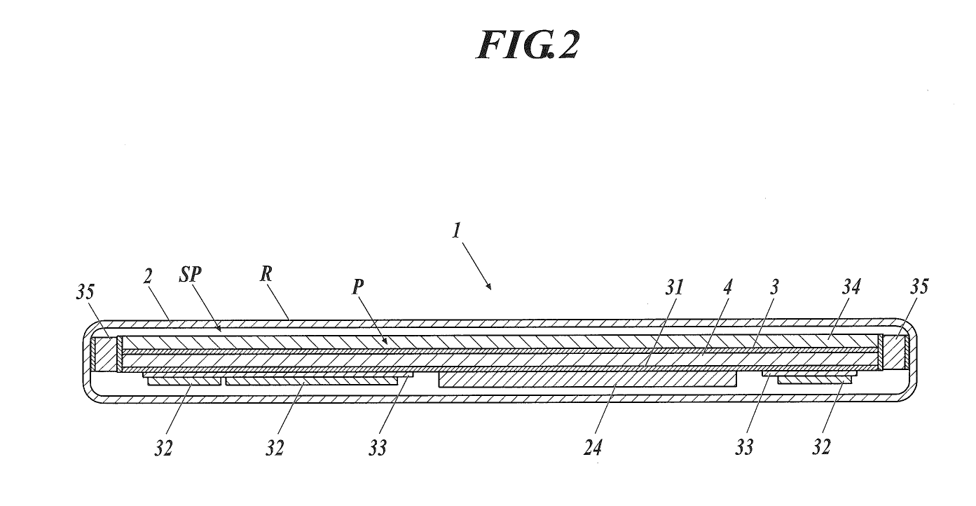

The configuration of a radiation image capturing device 1 in accordance with the present embodiment is described. FIG. 1 is a perspective view showing the appearance of the radiation image capturing device 1 in accordance with the present embodiment; and FIG. 2 is a cross-sectional view taken along the line X-X of FIG. 1. As shown in FIGS. 1 and 2, the radiation image capturing device 1 of the present embodiment includes a housing 2 which contains a sensor panel SP constituted of a scintillator 3, a substrate 4 and the like.

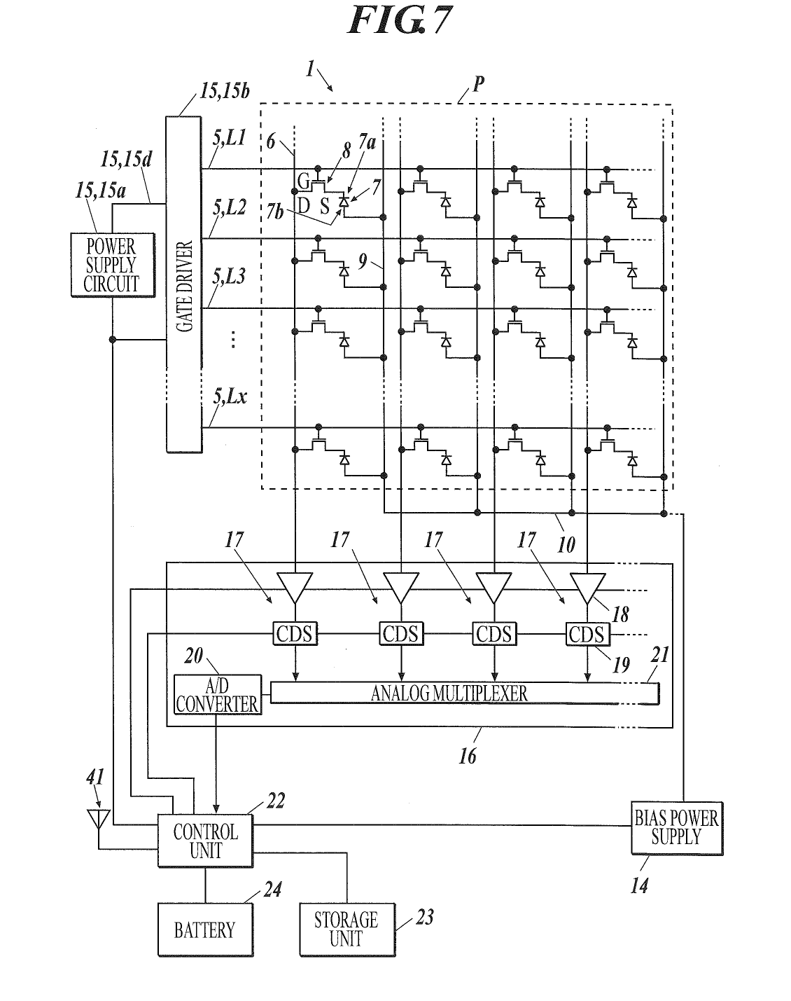

In the present embodiment, the housing 2 includes a housing main body 2A and covers 2B and 2C. The housing main body 2A is in a shape of a rectangular hollow cylinder with an opening at each side, and includes a radiation incidence plane R. The openings of the housing main body 2A are covered with the covers 2B and 2C. One cover 2B of the housing 2 is provided with a power switch 37, a changing-over switch 38, a connector 39 and indicators 40 constituted of LEDs, for example, to indicate the state of battery and the operational state of the radiation image capturing device 1. Further, the cover 2C on the other side of the housing 2 is provided with an antenna device 41 (not shown in FIG. 1; see FIG. 7 described later) for wireless communication with an external device.

As shown in FIG. 2, a base 31 is disposed in the housing 2. The substrate 4 is provided over a surface of the base 31 on the side of radiation incidence plane R, with a thin plate constituted of lead (not shown) disposed between the substrate 4 and the base 31. A scintillator 3 is provided on a scintillator substrate 34 over one surface of the substrate 4, with the scintillator 3 facing the substrate 4.

On the other side of the base 31, PCB substrates 33 each provided with an electronic component 32, a battery 24 and the like are provided. In this way, the sensor panel SP is constituted of the base 31, the substrate 4 and the like. Further, in the present embodiment, a shock-absorbing member 35 is provided between the sensor panel SP and each side of the housing 2.

In the following explanations, the directions (up/down) in the radiation image capturing device 1 are defined as follows: the side where the scintillator 3 and the scintillator substrate 34 are provided in FIG. 2 is referred to as “upper side”; and the side where the electronic components 32 and the battery 24 are provided in FIG. 2 is referred to as “lower side”.

The scintillator 3 is disposed so as to face a detector P (described later) of the substrate 4. In the present embodiment, the scintillator 3 contains fluorescent substance as its main component, for example. When radiation is incident on the scintillator 3, the scintillator 3 converts the incident radiation mainly into a light having a wavelength of 300 to 800 nm, i.e., visible light, and outputs it.

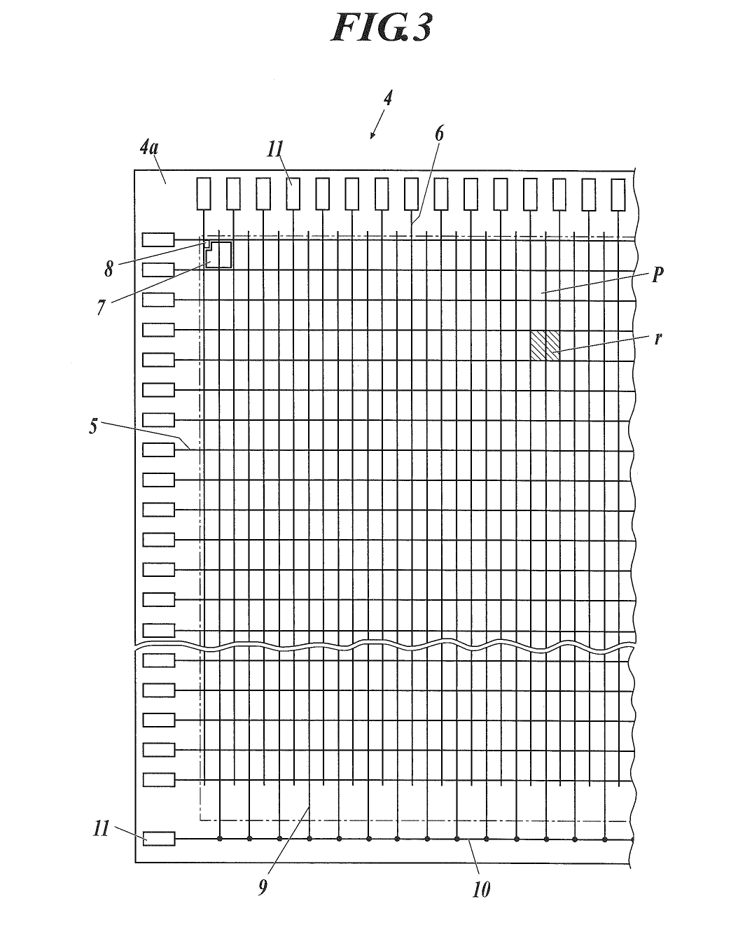

Further, in the present embodiment, the substrate 4 is constituted of a glass substrate. As shown in FIG. 3, a plurality of scan lines 5 and a plurality of signal lines 6 are arranged in such a way as to intersect each other on the surface 4a, facing the scintillator 3, of the substrate 4. A radiation detection element 7 is provided in each of small regions r formed by the scan lines 5 and the signal lines 6 on the surface 4a of the substrate 4.

The total area of the small regions r where a plurality of radiation detection elements 7 are two-dimensionally arranged, i.e., the area indicated by the chain line in FIG. 3, serves as the detector P.

When radiation is incident on the radiation incidence plane R of the housing 2 in the radiation image capturing device 1, and the light, such as visible light, into which the radiation has been converted at the scintillator 3 is sent, the radiation detection elements 7 generate electron-hole pairs therein. In this way, the radiation detection elements 7 convert the irradiated radiation (i.e., the light into which the radiation has been converted at the scintillator 3 in the present embodiment) into electric charge.

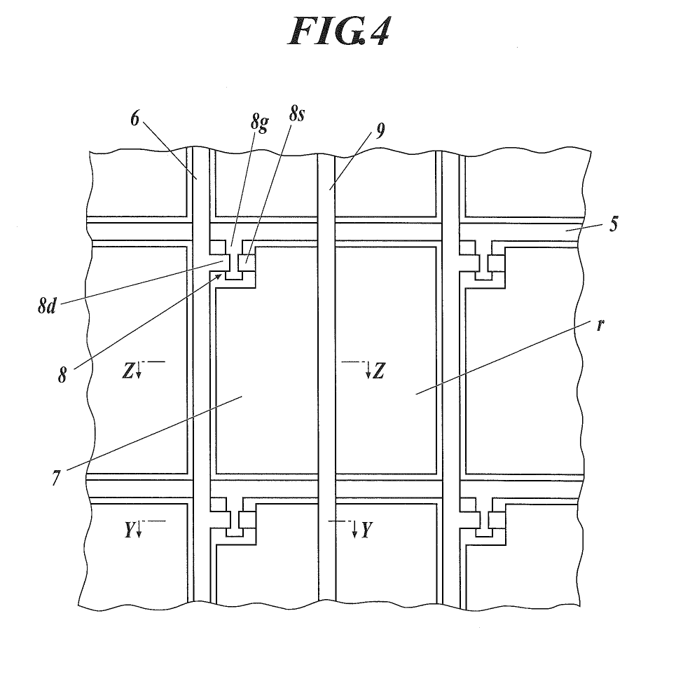

In the present embodiment, photodiodes are used as the radiation detection elements 7. Alternatively, phototransistors may be used, for example. Each of the radiation detection elements 7 is connected to a source electrode 8s of a TFT 8, which is a switch element, as shown in FIG. 4, which is an enlarged view of FIG. 3. A drain electrode 8d of a TFT 8 is connected to a signal line 6.

When an ON-state voltage is applied to a gate electrode 8g through a scan line 5 from a scan driving unit 15 (described later), the TFT 8 is put into an ON-state, and discharges the electric charge accumulated in the radiation detection element 7 to the signal line 6 through the source electrode 8s and the drain electrode 8d. When an OFF-state voltage is applied to the gate electrode 8g through the connected scan line 5, the TFT 8 is put into an OFF-state, stops the discharge of electric charge from the radiation detection element 7 to the signal line 6, and accumulates electric charge in the radiation detection element 7.

The configurations of each of the radiation detection elements 7 and each of the TFTs 8 as switch elements are described with reference to the cross-sectional view shown in FIG. 5. FIG. 5 is a cross-sectional view taken along the line Y-Y of FIG. 4.

The gate electrode 8g of the TFT 8 constituted of Al, Cr, or the like is formed on the surface 4a of the substrate 4, the surface 4a facing the scintillator 3 (not shown in FIG. 5; see FIG. 2). The gate electrode 8g is disposed thereon to be united with the scan line 5 (not shown).

The source electrode 8s connected to a first electrode 7a of the radiation detection element 7 and the drain electrode 8d formed to be united with the signal line 6 are provided above a gate insulating layer 81 and the gate electrode 8g, with a semiconductor layer 82 between the gate insulating layer 81 and the source electrode 8s and the drain electrode 8d. The gate insulating layer 81 is constituted of silicon nitride (SiNₓ) or the like, and disposed on the gate electrode 8g and the surface 4a. The semiconductor layer 82 is constituted of amorphous silicon hydride (a-Si) or the like.

The semiconductor layer 82 may be formed of amorphous silicon hydride (a-Si) as in the present embodiment, or may be formed of amorphous oxide or organic semiconductor material, for example.

The source electrode 8s and the drain electrode 8d are divided by a first passivation layer 83 constituted of silicon nitride (SiNₓ) or the like. The first passivation layer 83 covers the electrodes 8s and 8d from above. An ohmic contact layer 84a is disposed between the semiconductor layer 82 and the source electrode 8s. An ohmic contact layer 84b is disposed between the semiconductor layer 82 and the drain electrode 8d. Each of the ohmic contact layers 84a and 84b is formed by doping amorphous silicon hydride with a VI group element so as to be an n-type. As described above, the TFT 8 as a switch element is formed.

In the radiation detection element 7, an insulating layer 72 is formed on an insulating layer 71. The insulating layer 71 is formed to be united with the gate insulating layer 81 on the surface 4a of the substrate 4. The insulating layer 72 is formed to be united with the first passivation layer 83. The first electrode 7a constituted of AL, Cr, Mo, or the like is disposed on the insulating layer 72. The first electrode 7a is connected to the source electrode 8s of the TFT 8 via a hole H made in the first passivation layer 83.

An n layer 74, an i layer 75, and a p layer 76 are disposed on the first electrode 7a in the order named. The n layer 74 is formed by doping amorphous silicon hydride with a VI group element to be an n-type. The i layer 75 is constituted of amorphous silicon hydride, and is a transforming layer. The p layer 76 is formed by doping amorphous silicon hydride with a III group element to be a p-type.

In this case, organic photoelectric conversion material may be used instead of amorphous silicon hydride, for example.

When radiation enters from the radiation incidence surface R of the housing 2 of the radiation image capturing device 1, the scintillator 3 converts the radiation into light such as visible light; and the light after the conversion is sent from the above in the drawings. The light reaches the i layer 75 of the radiation detection element 7, and an electron-hole pair is generated in the i layer 75. Thus, the radiation detection element 7 converts the light sent from the scintillator 3, into electric charge.

On the p layer 76, a second electrode 7b of a transparent electrode such as an ITO (Indium Tin Oxide) is disposed and formed, so that the light reaches the i layer 75 and the like. In the present embodiment, as described above, the radiation detection element 7 is formed.

The p layer 76, the i layer 75 and the n layer 74 may be disposed in the order opposite to the order described above. In the present embodiment, as the radiation detection element 7, the so-called pin-type radiation detection element is used. The pin-type radiation detection element is formed, as described above, by the p layer 76, the i layer 75 and the n layer 74 being disposed in the order named. However, this is not a limit.

To the upper surface of the second electrode 7b of the radiation detection element 7, a bias line 9 (described later) is connected. The second electrode 7b, the bias line 9 in the radiation detection element 7, the first electrode 7a extending to the TFT 8 side, and the first passivation layer 83, i.e., the upper surface parts of the radiation detection element 7 and the TFT 8, are covered with a second passivation layer 78 constituted of silicon nitride (SiNₓ) or the like.

In the present embodiment, a flattening layer constituted of acrylic resin or the like is formed above the second passivation layer 78 to flatten the unevenness of the surface of the substrate 4 owing to the formation of the radiation detection elements 7 and the TFTs 8, although the flattening layer is not shown in FIG. 5 (described later; see FIG. 16, for example). The scintillator 3 (see FIG. 2) is disposed so as to be in contact with the flattening layer.

The detailed configuration as to the distance between edges of the radiation detection element 7 and edges of the scan line 5 and the signal line 6, for example, is described later.

As shown in FIG. 4, in the present embodiment, each bias line 9 is connected to a plurality of radiation detection elements 7 arranged in a column. The bias lines 9 are arranged parallel to the signal lines 6 as shown in FIG. 3. The bias lines 9 are connected to a connection line 10 outside of the detector P of the substrate 4.

In the present embodiment, as shown in FIG. 3, the scan lines 5, the signal lines 6, and the connection line 10 to which the bias lines 9 are connected are connected to input/output terminals (also referred to as pads) 11, respectively, which are disposed near the edges of the substrate 4.

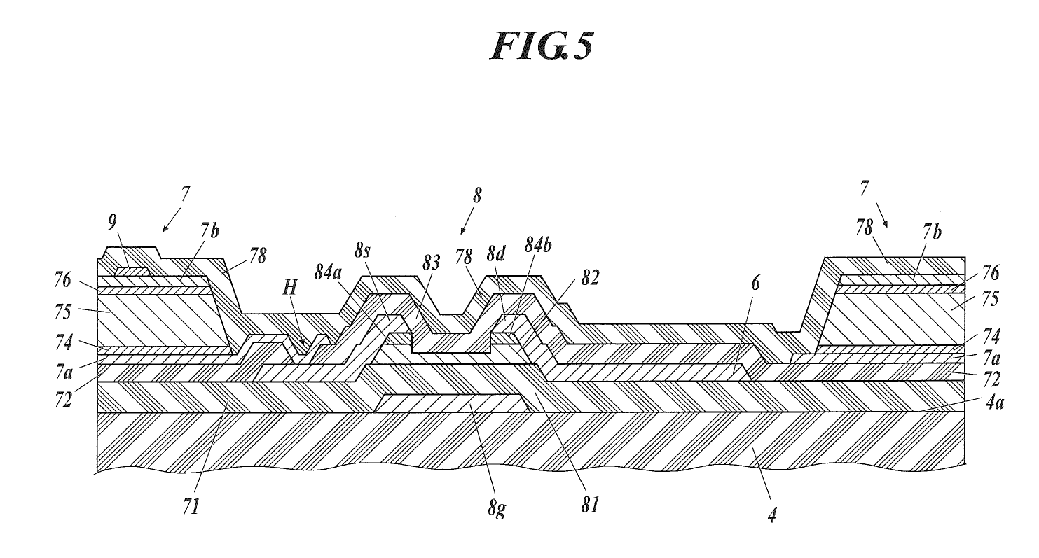

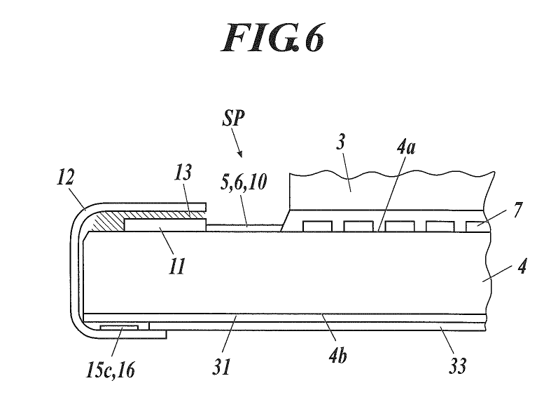

As shown in FIG. 6, a flexible circuit substrate (also referred to as Chip On Film) 12 is connected to each input/output terminal 11 through an anisotropic conductive adhesive material 13 such as an anisotropic conductive film or an anisotropic conductive paste. The flexible circuit substrate 12 has a film in which chips including a reading IC 16 and gate ICs 15c constituting a gate driver 15b of the scan driving unit 15 (described below) are built.

The flexible circuit substrate 12 extends to the back surface 4b of the substrate 4, and connected to the above-described PCB substrate 33 on the back surface 4b. Thus, the sensor panel SP of the radiation image capturing device 1 is formed. In FIG. 6, the electronic components 32 and the like are not shown.

Here, the circuit configuration of the radiation image capturing device 1 is described briefly. FIG. 7 is a block diagram showing an equivalent circuit of the radiation image capturing device 1 of the present embodiment.

As described above, in each radiation detection element 7 of the detector P of the substrate 4, a bias line 9 is connected to the second electrode 7b, and a plurality of bias lines 9 are connected to the connection line 10 so as to be connected to a bias power supply 14. The bias power supply 14 applies a reverse bias voltage to the second electrode 7b of each radiation detection element 7 via the connection line 10 and each bias line 9, the voltage being equal to or less than a voltage applied to the first electrode 7a of the radiation detection element 7.

The scan driving unit 15 includes a power supply circuit 15a and the gate driver 15b. The power supply circuit 15a supplies an ON-state voltage and OFF-state voltage to the gate driver 15b via a line 15d. The gate driver 15b switches the voltage to be applied to the lines L1 to Lx of the scan lines 5 between ON-state voltage and OFF-state voltage. In the present embodiment, the gate driver 15b is constituted of a plurality of gate ICs 15c (see FIG. 6) being arranged parallel to each other.

The signal lines 6 are connected to reading circuits 17 embedded in the reading IC 16. Each of the reading circuits 17 is constituted of an amplifier circuit 18, a correlated double sampling circuit 19 and the like. In the reading IC 16, an analog multiplexer 21 and an A/D converter 20 are further provided. In FIG. 7, each correlated double sampling circuit 19 is represented by “CDS”.

In the reading processing of image data D from the radiation detection elements 7 after performing radiation image capturing, when the TFTs 8, which are connected to the scan lines 5 to which the ON-state voltage is applied from the gate driver 15b of the scan driving unit 15, are turned on, electric charge is discharged from the radiation detection elements 7 to the signal lines 6 via the TFTs 8. Then, the discharged electric charge flows into the amplifier circuits 18.

Each of the amplifier circuits 18 outputs a voltage value in accordance with the charge amount which has flowed thereinto. Each of the correlated double sampling circuits (CDS) 19 calculates a difference Vfi−Vin between the voltage values Vfi and Vin, and outputs the calculated difference Vfi−Vin as analog image data D to the downstream side. The voltage value Vin is the value outputted from the amplifier circuit 18 before the electric charge flows from the radiation detection element 7, and the voltage value Vfi is the value outputted from the amplifier circuit 18 after the electric charge flows from the radiation detection element 7.

The image data D outputted from each of the correlated double sampling circuits 19 is transmitted to the A/D converter 20 consecutively via the analog multiplexer 21. Then, the image data D is converted into digital image data consecutively by the A/D converter 20, outputted to the storage unit 23, and stored therein. The processing as described above is performed for each of the radiation detection elements 7, and as a result, image data D is read from each of the radiation detection elements 7 and stored in the storage unit 23.

The control unit 22 is constituted of a computer in which a not-shown CPU (Central Processing Unit), a ROM (Read Only Memory), a RAM (Random Access Memory), an input/output interface, and the like are connected by a bus; a FPGA (Field Programmable Gate Array); or the like. The control unit 22 may be constituted of a control circuit for exclusive use.

The control unit 22 controls the operations of the components of the radiation image capturing device 1, and configured to perform the reading processing of image data D as described above, for example. Furthermore, the storage unit 23 is connected to the control unit 22 as shown in FIG. 7. The storage unit 23 is constituted of a SRAM (Static RAM), SDRAM (Synchronous DRAM) or the like.

Further, in the present embodiment, the above-described antenna device 24 is connected to the control unit 22. Furthermore, a battery 41 to supply power to the components of the sensor panel SP is connected to the control unit 22.

Next, the configuration of the present embodiment, which enables reading of image data D from each radiation detection element 7 with a high signal-to-noise ratio (hereinafter referred to as S/N), is described in detail. Also, the behavior of the radiation image capturing device 1 in accordance with the present embodiment is described.

FIG. 8 is a view of scan lines 5, signal lines 6 and a radiation detection element 7 related to only one pixel (i.e., for one radiation detection element 7) of the sensor panel SP of the radiation image capturing device 1 in accordance with the present embodiment. In FIG. 8, the TFTs 8 as switch elements, the bias lines 9 (see FIG. 4), and the like are not shown.

In the following description, the first distance between an edge of the radiation detection element 7 and an edge of the corresponding scan line 5, and the second distance between an edge of the radiation detection element 7 and an edge of the corresponding signal line 6 are both L1 μm; and the first interval between edges of adjacent scan lines 5, and the second interval between edges of adjacent signal lines 6 are both L2 μm. The first and second distances are hereinafter simply referred to as “distance L1”; and the first and second intervals are hereinafter simply referred to as “interval L2” or “pixel pitch L2”, as shown in FIG. 8.

In order to read image data D from each of the radiation detection elements 7 at a high S/N as mentioned above, “S” (signal value; i.e., the value of image data D) should be larger, and “N” (noise; i.e., the noise superimposed on image data D) should be smaller.

In order to make the signal value (i.e., the value of image data D) as large as possible as mentioned above, the aperture ratio of the radiation detection element 7 (i.e., the area Sa) should be as large as possible for the pixel pitch L2.

As the area Sa of the radiation detection element 7 is larger for a given pixel pitch L2, however, the distance L1 becomes smaller. Further, as the distance L1 becomes smaller, the first parasitic capacitance formed between the radiation detection element 7 and the scan line 5, and the second parasitic capacitance formed between the radiation detection element 7 and the signal line 6 become larger. The first and second parasitic capacitances are hereinafter simply referred to as a “parasitic capacitance C”.

When the parasitic capacitance C becomes larger, a signal line capacitance increases. As a result, a noise in the reading circuit 17 increases in proportion to the signal line capacitance, leading to deterioration in the S/N of image data D read from the radiation detection element 7.

In view of such circumstances, the inventors have spent a lot of time on conducting studies to find what value the distance L1 should be set to for increasing the value of image data D and reducing the noise superimposed on the image data D. In other words, the inventors have made efforts to find an appropriate distance L1 for improving the S/N.

As a result, the following very important features have been found:
(A) For a given pixel pitch L2, the S/N varies depending on the distance L1. A distance L1max which maximizes the S/N (i.e., which produces the best S/N) exists. That is, there is a peak in the S/Ns.
(B) The distance L1max which maximizes the S/N varies depending on the pixel pitch L2 (i.e., the interval L2).

It has also been found that the distance L1max which maximizes the S/N substantially has a linear dependence with the pixel pitch L2, and that the distance L1max can be approximated by a linear function of the pixel pitch L2, as described later.

The detailed explanations are given below. In the following, the area Sa of the radiation detection element 7 is used as the value equivalent to “S” (signal value; i.e., the value of image data D), by using the fact that the “S” is proportional to the area Sa. Further, as described above, the parasitic capacitance C is used as the value equivalent to “N” (noise), by using the fact that the “N” increases as the parasitic capacitance C increases. That is, the following explanations are given on the basis that

S/N=Sa/C (1)

holds.

When the radiation detection element 7 is formed with the pixel pitch L2 set to 175 μm, for example, and with the distance L1 changed variously, the area Sa of the radiation detection element 7 is expressed by

Sa=(175 [μm]−2×L1)² (2).

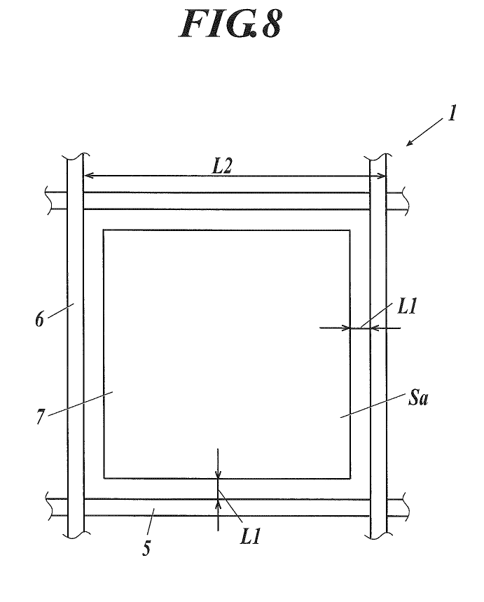

As shown in FIG. 9A, the area Sa of the radiation detection element 7 decreases as the distance L1 increases when the distance L1 falls within the range of about 10 to 20 μm, for example.

When each of the radiation detection elements 7 is formed as described above, and the parasitic capacitance C is measured, the parasitic capacitance C decreases in inverse proportion to the distance L1 as shown in FIG. 9B.

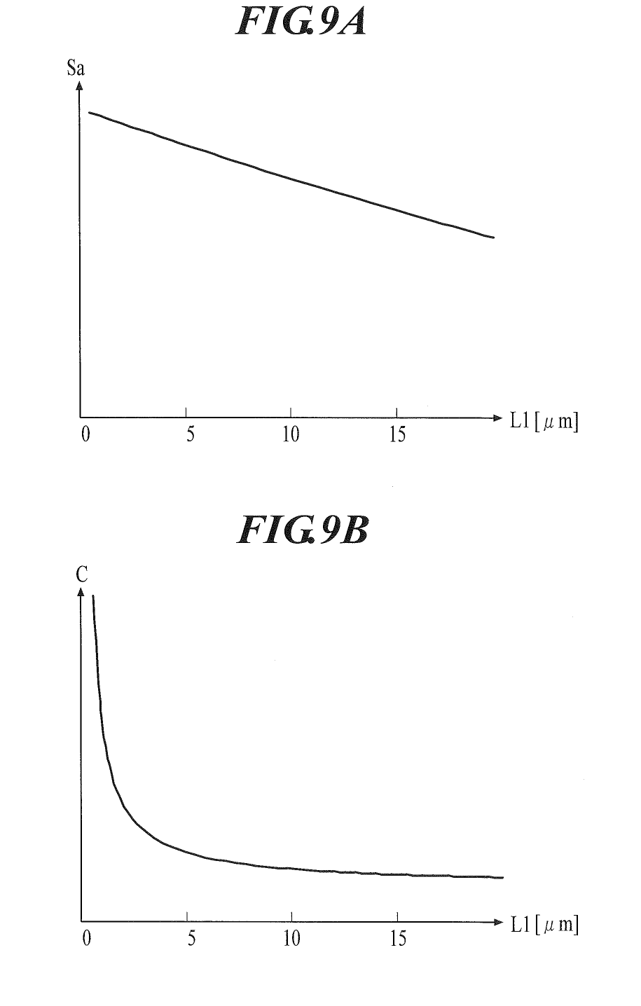

When the area Sa of the radiation detection element 7 calculated as described above and the measured parasitic capacitance C for each distance L1 are substituted into the expression (1), and the calculated S/N is plotted for each distance L1, it has been found that there is the relation shown in FIG. 10 between the S/N and the distance L1.

As indicated by the arrow in FIG. 10, there is a peak in the calculated S/Ns. Specifically, in the case where the pixel pitch L2 is 175 μm, for example, the S/N becomes a maximum value when the distance L1 is about 11 μm. That is, in the case where the pixel pitch L2 is 175 μm, the distance L1max which maximizes the S/N is about 11 μm.

Similarly, when the radiation detection element 7 is formed with the pixel pitch L2 set to 100 μm, for example, and with the distance L1 changed variously, the area Sa of the radiation detection element 7 is expressed by

Sa=(100 [μm]−2×L1)² (3).

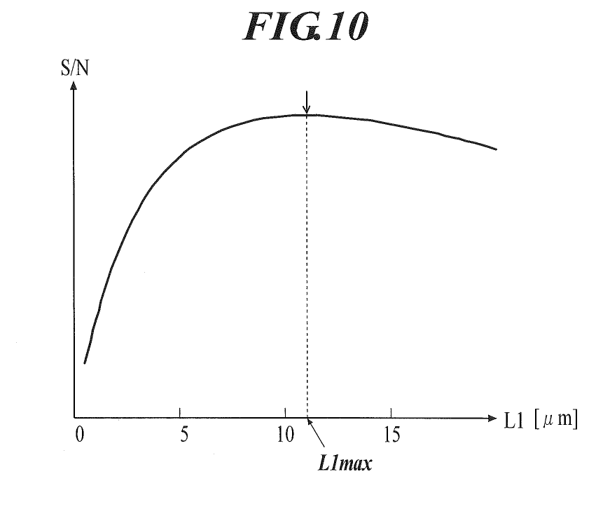

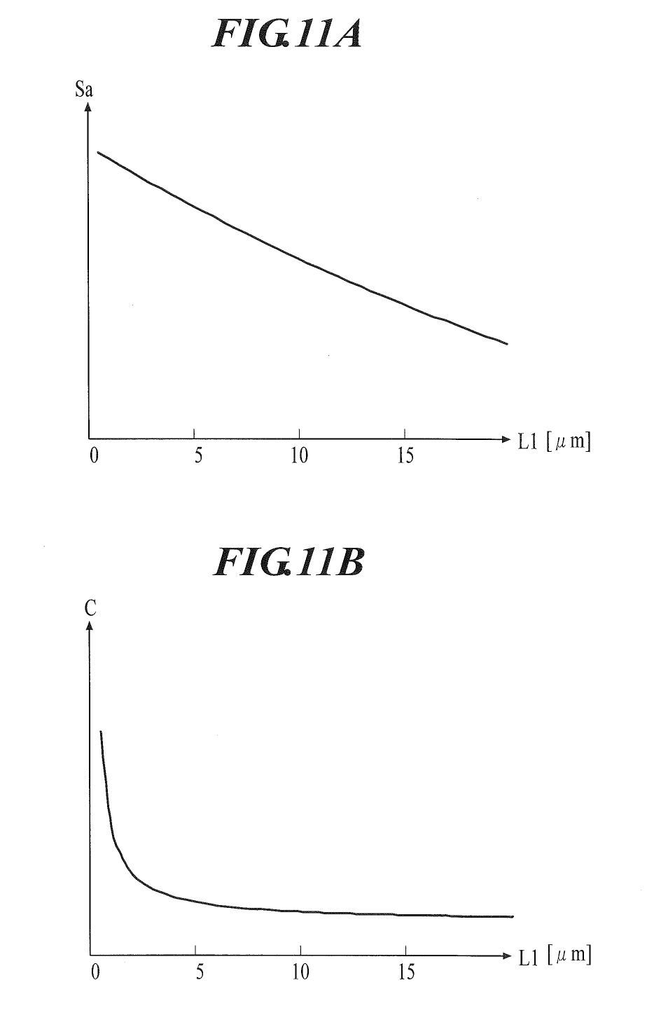

As shown in FIG. 11A, the area Sa of the radiation detection element 7 decreases as the distance L1 increases when the distance L1 falls within the range of about 10 to 20 μm, for example.

When each of the radiation detection elements 7 are formed as described above and the parasitic capacitance C is measured, the parasitic capacitance C decreases in inverse proportion to the distance L1 as shown in FIG. 11B.

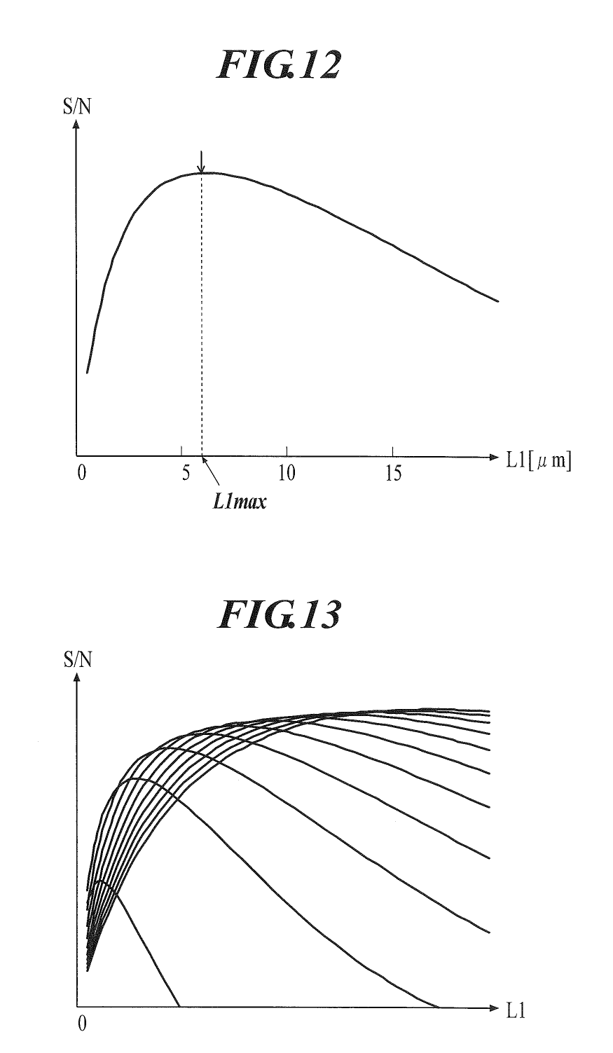

When the S/N calculated from the expression (1) based on the area Sa of the radiation detection element 7 and the parasitic capacitance C is plotted for each distance L1, there is the relation shown in FIG. 12 between the S/N and the distance L1.

As indicated by the arrow in FIG. 12, there is a peak in the calculated S/Ns. Specifically, in the case where the pixel pitch L2 is 100 μm, for example, the S/N becomes a maximum value when the distance L1 is about 6.3 μm.

Thus, the S/N varies depending on the distance L1 for the given pixel pitch L2 (e.g., 175 μm or 100 μm in the case described above). It has been found that the distance L1max which maximizes the S/N exists. In other words, it has been found that there is a peak in the S/Ns (see the feature (A) stated above).

Further, as the above-described examples show, it has also been found that the distance L1max which maximizes the S/N varies depending on the pixel pitch L2 (i.e., the interval L2) (see the feature (B) stated above).

The pixel pitch L2 is often set to a value within the range of 50 to 250 μm from a practical standpoint. When the curve of S/N for the distances L1 shown in FIGS. 10 and 12 is calculated while the pixel pitch L2 is varied by 25 μm within the range of 50 to 250 μm, a curve is obtained for each pixel pitch L2 as shown in FIG. 13.

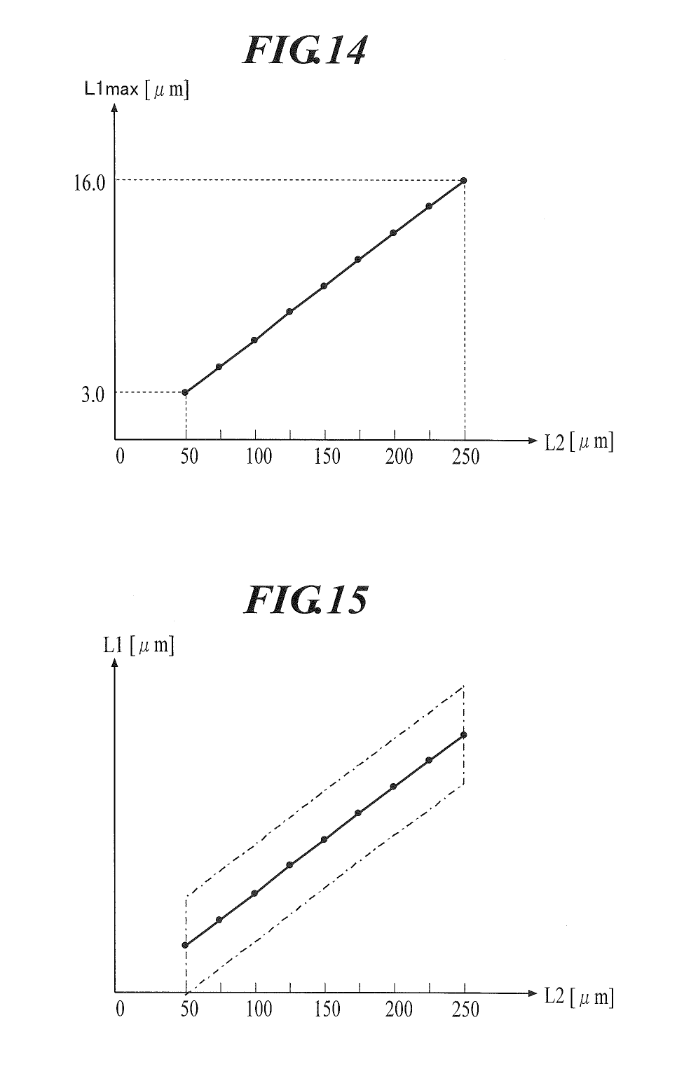

The distance L1max which maximizes the S/N, i.e., the peak of S/N, varies depending on the curve. In other words, the peak of S/N varies depending on the pixel pitch L2. When the distance L1max which maximizes the S/N is plotted for each pixel pitch L2, the relation as shown in FIG. 14 is obtained.

As shown in FIG. 14, it has been found that the distance L1max which maximizes the S/N substantially has a linear dependence with the pixel pitch L2. Therefore, the distance L1max which maximizes the S/N can be approximated by a linear function of the pixel pitch L2. Since the distance L1max which maximized the S/N was 3.0 μm when the pixel pitch L2 was 50 μm, and the distance L1max which maximized the S/N was 16.0 μm when pixel pitch L2 was 250 μm, it has been found that the linear function as an approximate expression can be expressed by

L1max=0.065×L2−0.25 (4).

The manufacturing errors of the radiation detection element 7, the scan line 5 and the signal line 6 on the surface 4a of the substrate 4 (see FIG. 5) are estimated to be at least about 3 μm. Therefore, when the ideal distance L1 for a set pixel pitch L2 is the distance L1max calculated as described above, the distance L1 is set to a value within the range between (L1max−3) μm to (L1max+3) μm actually. The value of “3 μm” is acceptable as a manufacturing error.

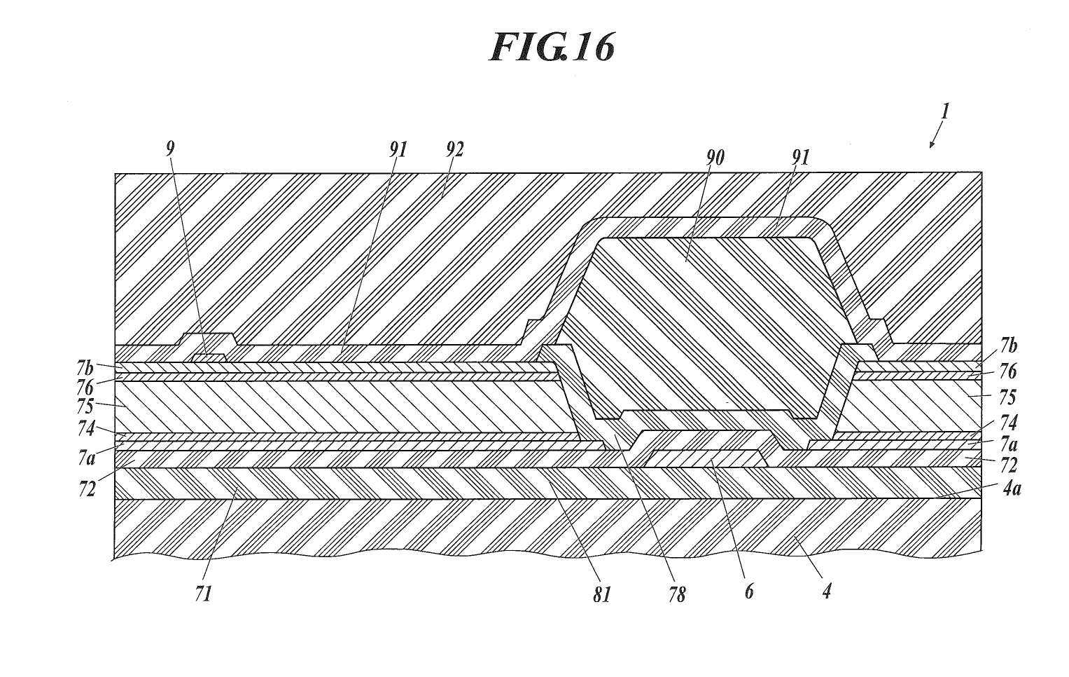

In the radiation image capturing device 1 in accordance with the present embodiment, when the pixel pitch L2 (i.e., the interval L2) is set to an interval within the range of 50 to 250 μm from a practical standpoint for the radiation image capturing device 1, the distance L1 is set to a value within the range of (expression (4) ±3) μm (i.e., within the range enclosed by the chain line in FIG. 15), as shown in FIG. 15.

That is, in the present embodiment, the relation of

0.065×L2−0.25−3≦L1≦0.065×L2−0.25+3 (5)

holds between the distance L1 and the pixel pitch L2. The radiation detection elements 7 are arranged in the respective small regions r (see FIGS. 3 and 4) formed by the scan lines 5 and the signal lines 6, such that the relation holds.

As shown in FIGS. 10 and 12, the S/N for the value of L1 which falls within the range of L1max±3 μm (where L1max is the distance which maximizes the S/N) is almost the same as the S/N for the distance L1max.

According to the studies conducted by the inventors, it has been known that there is no change in the relational expression (5) when the widths and thicknesses of the scan lines 5 and the signal lines 6 are varied. The parasitic capacitance C may vary according to the material of the insulating layer, such as silicon nitride (SiNₓ), disposed between the radiation detection element 7 and the scan line 5, and between the radiation detection element 7 and the signal line 6. The parasitic capacitance C, however, does not vary so much according to the material in actuality.

As stated above, according to the radiation image capturing device 1 in accordance with the present embodiment, the distance L1 is set to an optimum value by using at least the feature (A) stated above, which has been found concerning how the S/N is influenced by the radiation detection element 7, the scan line 5 and the signal line 6.

That is, it has been found that, for a given pixel pitch L2 (i.e., the interval L2), the S/N varies depending on the distance L1. Further, it has been found that a distance L1max which maximizes the S/N (i.e., which produces the best S/N) exists. In other words, it has been found that there is a peak in the S/Ns (see the feature (A) stated above).

Further, in the radiation image capturing device 1 in accordance with the present embodiment, each of the radiation detection elements 7 is formed such that the distance L1 is set to a distance not less than the distance obtained by subtracting a distance acceptable as a manufacturing error from the distance L1max which maximizes the S/N and not more than the distance obtained by adding a distance acceptable as a manufacturing error to the distance L1max which maximizes the S/N.

Therefore, in the radiation image capturing device 1, image data D can be read with a high S/N from the radiation detection elements 7 formed in the above-described way. Further, images of high quality can be formed based on the image data D with the high S/N.

Further, according to the studies conducted by the inventors, the feature (B) as stated above has been found. That is, the distance L1max which maximizes the S/N varies depending on a pixel pitch L2 (i.e., the interval L2).

For this reason, the distance L1max which maximizes the S/N is obtained as a function of a pixel pitch L2, and each of the radiation detection elements 7 is formed such that the distance L1 is set to a distance not less than the distance obtained by subtracting a distance acceptable as a manufacturing error from the distance L1max and not more than the distance obtained by adding a distance acceptable as a manufacturing error to the distance L1max.

Such a configuration enables formation of each radiation detection element 7 with the distance L1 at an optimum value according to a set pixel pitch L2, when the pixel pitch L2 has various values. Therefore, image data D can be read with a high S/N even when the pixel pitch L2 varies, and images of high quality can be formed based on the image data D with the high S/N.

In the above-described embodiment, the relation between the distance L1max which maximizes the S/N and the pixel pitch L2 is approximated by the linear function expressed by the expression (4), as shown in FIG. 14. Alternatively, the relation may be approximated by an n^{th} order function, such as a quadratic function, or an exponent function.

In the above-described embodiment, the first distance between an edge of the radiation detection element 7 and an edge of the scan line 5, and the second distance between an edge of the radiation detection element 7 and an edge of the signal line 6 are set to the same value “L1”; and the first interval between adjacent scan lines 5, and the second interval between adjacent signal lines 6 are set to the same value “L2”. Alternatively, the first and second distances may be set to values different from each other; and/or the first and second intervals may be set to values different from each other. In such a case, at least one of the following (i) and (ii) holds: (i) the first distance L1 and the first interval L2 satisfy the relation described in the above-described embodiment; (ii) the second distance L1 and the second interval L2 satisfy the relation described in the above-described embodiment.

Further, in the above-described embodiment, when the distance L1 is varied for a given pixel pitch L2, the distance L1max which maximizes the S/N exists. Using such a feature, the distance L1 is set to the distance L1max or set within a range acceptable as a manufacturing error, the center of which range is the distance L1max, so that the S/N of image data D to be read is increased.

Alternatively, the S/N of image data D to be read may be improved by increasing “S” (signal), that is, by increasing the value of the image data D itself to be read. In order to increase the value of the image data D itself to be read, the following configuration may be employed.

Specifically, FIG. 5 shows the case where the second passivation layer 78 is provided on the upper surface of the second electrode 7b, which is a transparent electrode of the radiation detection element 7, to cover and protect the second electrode 7b. Alternatively, the inorganic protective layer including the second passivation layer 78 may be provided only on the part except the upper surface of the second electrode 7b (i.e., except the surface facing the scintillator 3).

Before describing such a configuration, a conventional case is described. FIG. 16 is a cross-sectional view of a conventional radiation detection element 7, the view taken along the line Z-Z of FIG. 4. The configuration of the surface 4a of the substrate 4 and the layer-stack configuration of the radiation detection element 7 are the same as those described above with reference to FIG. 5.

Above the second passivation layer 78 which covers the signal lines 6, the scan lines 5 and the TFTs 8 (not shown), an organic protective layer 90 constituted of acrylic or the like is heaped and formed. Then, an inorganic protective layer 91 constituted of silicon nitride (SiNₓ), silicon oxide (SiOₓ) or the like is formed so as to cover all the structures provided on the substrate 4 including the organic protective layer 90, the second electrode 7b and the bias line 9.

A flattening layer 92, which is constituted of acrylic or the like, is provided over the inorganic protective layer 91 to flatten the unevenness of the inorganic protective layer 91 owing to the unevenness of the structures formed on the substrate 4. The scintillator 3 (not show in FIG. 16; see FIG. 2) is disposed so as to be in contact with the flattening layer 92 from above.

In such a configuration, however, although the inorganic protective layer 91 constituted of silicon nitride (SiNₓ) or silicon oxide (SiOₓ) is transparent, a certain proportion of the light sent from the scintillator 3 is absorbed by the inorganic protective layer 91 when passing through the inorganic protective layer 91. This reduces the amount of light that reaches the radiation detection element 7, resulting in decrease in the value of image data D to be read as electric charge into which light is converted at the radiation detection element 7.

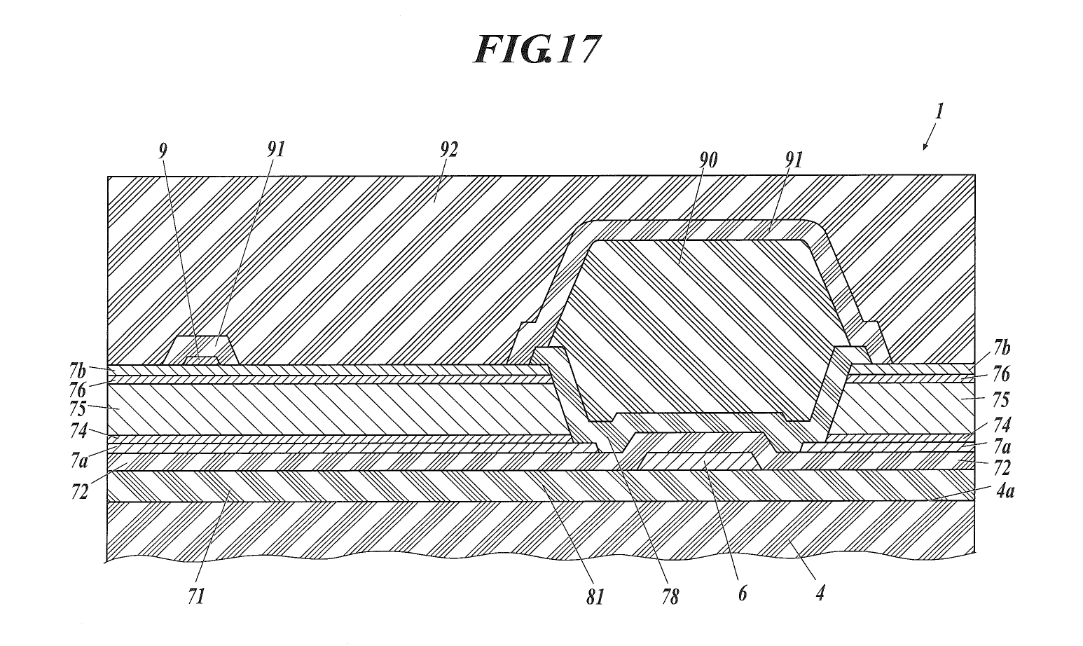

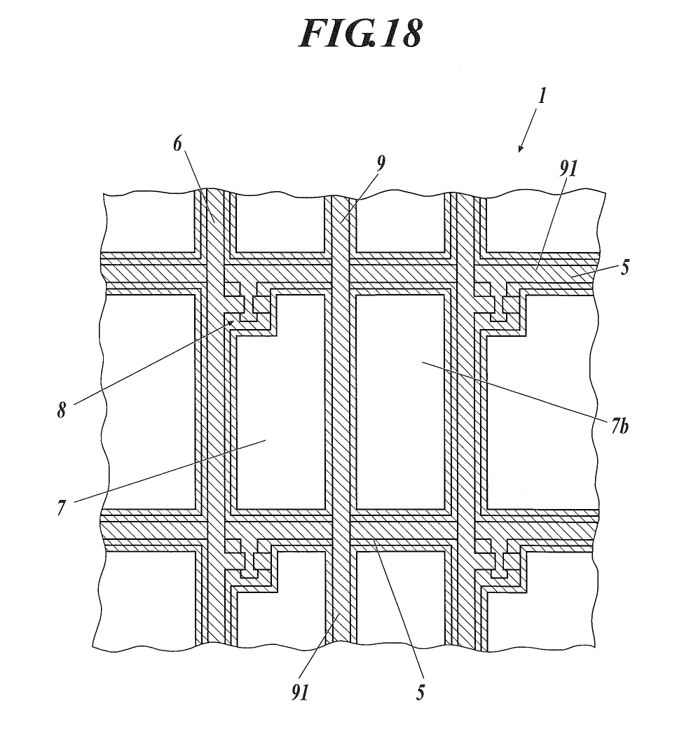

In view of the above, the inorganic protective layer 91 may be provided only on the part except the upper surface of the second electrode 7b, for example, as shown in FIG. 17. In other words, the inorganic protective layer 91 may be provided only on the part on the organic protective layer 90 heaped and formed over the signal line 6.

Such a configuration allows the radiation sent to the radiation image capturing device 1 to be converted into light at the scintillator 3, and allows the light to reach the radiation detection element 7 without passing through the inorganic protective layer 91. Therefore, unlike the conventional case, the light is not absorbed by the inorganic protective layer 91, and a decrease in the amount of light that reaches the radiation detection element 7 is prevented.

Since a large amount of light reaches each of the radiation detection elements 7 in this way, it is possible to increase the value of image data D to be read from the radiation detection elements 7. Thus, “S” (signal i.e., the value of the image data D itself to be read) is increased, which results in an improvement of the S/N of image data D to be read.

In order to form the inorganic protective layer 91 over a part except the second electrode 7b, the inorganic protective layer 91 is first formed over all the structures provided on the substrate 4 including the second electrode 7b, and after that, the inorganic protective layer 91 over the second electrode 7b is removed through photolithography, for example.

If, however, the inorganic protective layer 91 which covers the bias line 9 formed on the second electrode 7b is removed, too, the bias line 9 is also removed along with the inorganic protective layer 91 because the bias line 9 is constituted of aluminum or the like and is subject to corrosion. If the bias line 9 is removed, the bias line 9 breaks and as a result, a reverse bias voltage cannot be applied to each of the radiation detection elements 7.

In view of the above, the inorganic protective layer 91 preferably remains on the metal line part of the bias line 9 formed on the second electrode 7b, as shown in FIG. 17.

In this case, the inorganic protective layer 91 is formed at the shaded area in FIG. 18, which is a view showing this part seen from above; and the inorganic protective layer 91 is not formed over the other area, i.e., not formed over the second electrode 7b.

It should be understood that the present invention is not limited to the above-described embodiments, and may be modified as appropriate without departing from the spirit and scope of the present invention.

The entire disclosure of Japanese Patent Application No. 2012-117063 filed on May 23, 2012 including description, claims, drawings, and abstract are incorporated herein by reference in its entirety.

Although various exemplary embodiments have been shown and described, the invention is not limited to the present embodiments shown. Therefore, the scope of the invention is intended to be limited solely by the scope of the claims that follow.

What is claimed is:

1. A radiation image capturing device comprising:
a plurality of scan lines;
a plurality of signal lines arranged to intersect the scan lines;
a plurality of radiation detection elements respectively disposed in regions formed by the scan lines and the signal lines;
a plurality of switch elements which are connected to the scan lines, and discharge electric charge accumulated in the radiation detection elements to the signal lines when an ON-state voltage is applied to the scan lines,
wherein, with respect to each of the radiation detection elements, a first distance between an edge of the radiation detection element and an edge of a scan line of the scan lines and/or a second distance between an edge of the radiation detection element and an edge of a signal line of the signal lines is set within a range acceptable as a manufacturing error; and
wherein the center of the range is a value which maximizes a ratio obtained by dividing the area of the radiation detection element by a first parasitic capacitance between the radiation detection element and the scan line and/or a second parasitic capacitance between the radiation detection element and the signal line.

2. The radiation image capturing device according to claim 1, wherein the relation of 0.065×L2−0.25−3≦L1≦0.065×L2−0.25+3 is satisfied, wherein L1 represents the first distance and/or the second distance, and L2 represents a first interval between edges of adjacent scan lines of the scan lines and/or a second interval between edges of adjacent signal lines of the signal lines, L2 being within a range of 50 to 250 μm.
